(19) United States
(12) Patent Application Publication
(10) Pub. No.: US 2025/0299633 A1
(43) Pub. Date: Sep. 25, 2025

(54) DISPLAY PANEL AND DISPLAY APPARATUS

(71) Applicants: Wuhan Tianma Microelectronics Co., Ltd. Shanghai Branch, Shanghai (CN); Wuhan Tianma Microelectronics Co., Ltd., Wuhan (CN)

(72) Inventors: Mengmeng ZHANG, Shanghai (CN); Yuantao WU, Shanghai (CN)

(21) Appl. No.: 19/228,705

(22) Filed: Jun. 4, 2025

(30) Foreign Application Priority Data
Dec. 31, 2024 (CN) 202412000073.7

(51) Int. Cl. G09G 3/3233; H10K 59/121

(52) U.S. Cl. CPC G09G 3/3233; G09G 2300/0819; G09G 2300/0842; G09G 2300/0861; G09G 2310/08; G09G 2320/0247; G09G 2340/0435; H10K 59/1213

(57) ABSTRACT

The present disclosure provides a display panel and a display apparatus. The display panel includes a pixel circuit, and the pixel circuit includes a driving transistor, a light-emitting control transistor and a light-emitting device; the driving transistor is electrically connected to a power supply voltage terminal and the light-emitting control transistor, respectively; the light-emitting control transistor is electrically connected to the light-emitting device, and a gate of the light-emitting control transistor is connected to a light-emitting control signal line to receive the light-emitting control signal transmitted by the light-emitting control signal line; a plurality of pulses of the light-emitting control signal include a first pulse and a second pulse, and a non-enable level duration of the first pulse is greater than a non-enable level duration of the second pulse; in the first display mode, a picture refresh frame of the display panel includes a data writing frame, and in the data writing frame, the frequency of the light-emitting control signal is greater than a reference refresh frequency of the display panel. The technical solution solves the problem in the prior art that the unequal width design of the light-emitting control signal for the display screen with a low fundamental frequency is easily perceived by the human eye as flickering.

### CROSS-REFERENCE TO RELATED APPLICATION

The present application claims priority to Chinese Patent Application No. 202412000073.7, filed on Dec. 31, 2024, the content of which is incorporated herein by reference in its entirety.

### TECHNICAL FIELD

The present disclosure relates to the technical field of displaying, and, in particular, to a display panel and a display apparatus.

### BACKGROUND

In present display panels, a multi-pulse design scheme is generally used in the light-emitting control of the pixel driving circuit based on the light-emitting control signal. The number of pulses and the pulse width of the light-emitting control signal will affect the display effect of the display panel. For display panels with a low fundamental frequency, different widths between different pulses of the light-emitting control signal in one display cycle may cause flickering to be recognized by the user, so as to affect the user's experience.

### SUMMARY

The main purpose of the present disclosure is to provide a display panel and a display apparatus to solve the problem in the prior art that, for the display screen with a low fundamental frequency, the design of unequal widths of the light-emitting control signal is prone to causing flickering to be perceived by the human eye.

To achieve the above purpose, an aspect of the present disclosure provides a display panel, including a pixel circuit, the pixel circuit includes a driving transistor, a light-emitting control transistor and a light-emitting device. A first electrode of the driving transistor is electrically connected to a power supply voltage terminal, and a second electrode of the driving transistor is electrically connected to a first electrode of the light-emitting control transistor. A second electrode of the light-emitting control transistor is electrically connected to an electrode of the light-emitting device, and a gate of the light-emitting control transistor is connected to a light-emitting control signal line to receive a light-emitting control signal transmitted by the light-emitting control signal line. In one cycle of the light-emitting control signal, the light-emitting control signal includes a plurality of pulses, one of the pulses includes one non-enable level and one enable level that are adjacent to each other, the plurality of pulses of the light-emitting control signal include a first pulse and a second pulse, a non-enable level duration of the first pulse is S1, a non-enable level duration of the second pulse is S2, and S1>S2. A reference refresh frequency of the display panel is F0, in a first display mode, one picture refresh frame of the display panel includes a data writing frame, a frequency of the light-emitting control signal in the data writing frame is F1, and F1>F0.

In some embodiments of the present disclosure, in one cycle of the light-emitting control signal, the number of the first pulses of the light-emitting control signal is N1, the number of the second pulses is N2, N2=k1×N1, where k1 is a positive integer, and k1≥2.

In some embodiments of the present disclosure, N1 is negatively correlated with F0, and N2 is positively correlated with F0.

In some embodiments of the present disclosure, one cycle of the light-emitting control signal includes a plurality of groups of pulses, and one of the groups of pulses includes one first pulse and a plurality of second pulses subsequent to the first pulse.

In some embodiments of the present disclosure, in the first display mode, one picture refresh frame of the display panel further includes M light-emitting holding frames, and M≥1. In the light-emitting holding frames, the frequency of the light-emitting control signal is F1.

In some embodiments of the present disclosure, F1=k2×F0, where k2 is a positive integer, and k2≥2.

In some embodiments of the present disclosure, S1=k3×S2, where k3 is a positive integer, and k3≥2.

In some embodiments of the present disclosure, the pixel circuit further includes a data writing transistor and a bias adjustment transistor. A first electrode of the data writing transistor is electrically connected to a data line, and a second electrode of the data writing transistor is electrically connected to the first electrode of the driving transistor. A first electrode of the bias adjustment transistor is electrically connected to the first electrode of the driving transistor, a second electrode of the bias adjustment transistor is electrically connected to a bias adjustment signal line, and a gate of the bias adjustment transistor is electrically connected to a first scanning signal line to receive a first scanning signal. In the data writing frame, a number of cycles of the light-emitting control signal is N, and N≥2. One pulse of the first scanning signal includes an enable level and a non-enable level. The enable level of the first scanning signal overlaps with the non-enable level of the first pulse of the light-emitting control signal.

In some embodiments of the present disclosure, the reference refresh frequency F0 of the display panel satisfies F0≤90 Hz.

In some embodiments of the present disclosure, the reference refresh frequency F0 of the display panel is 60 Hz or 45 Hz.

In some embodiments of the present disclosure, the display panel further includes a driving circuit, and the driving circuit includes a light-emitting driver configured to generate the light-emitting control signal. The light-emitting driver includes a plurality of stages. Each of the plurality of stages receives an input signal, a first clock signal, a second clock signal, a first power supply voltage and a second power supply voltage, and outputs the light-emitting control signal. Each of the plurality of stages includes: an input module configured to receive and respond to the input signal and the first clock signal to output a stage transmission to a previous stage; a first output control module configured to receive the first power supply voltage and the second power supply voltage, and respond to the first clock signal and the second clock signal, to generate a first node voltage; a second output control module configured to receive the first power supply voltage and the second power supply voltage, and respond to the first clock signal and the second clock signal to generate a second node voltage; and an output module configured to receive the first power supply voltage and the second power supply voltage, and respond to the first node voltage and the second node voltage to generate the light-emitting control signal.

In some embodiments of the present disclosure, the input module includes a first switching transistor, a control terminal of the first switching transistor receives the first clock signal, a first terminal of the first switching transistor receives the input signal, and a second terminal of the first switching transistor is an output terminal.

In some embodiments of the present disclosure, the first output control module includes a second switching transistor, a third switching transistor, a fourth switching transistor, a fifth switching transistor and a sixth switching transistor, a control terminal of the second switching transistor receives the first clock signal, a second terminal of the second switching transistor and a control terminal of the fourth switching transistor receive the second power supply voltage, a first terminal of the second switching transistor is connected to a control terminal of the third switching transistor and a first terminal of the fourth switching transistor, respectively, a first terminal of the third switching transistor is connected to a second terminal of the fourth switching transistor and a first terminal of the fifth switching transistor, a second terminal of the third switching transistor and a control terminal of the fifth switching transistor receive the second clock signal, a second terminal of the fifth switching transistor is connected to a second terminal of the sixth switching transistor, a first terminal of the sixth switching transistor receives the first power supply voltage, and a control terminal of the sixth switching transistor is connected to an output terminal of the input module, and the second terminal of the sixth switching transistor outputs the first node voltage.

In some embodiments of the present disclosure, the first output control module further includes a first capacitor, a first plate of the first capacitor is connected to the second terminal of the fourth switching transistor, and a second plate of the first capacitor is connected to the first terminal of the third switching transistor.

In some embodiments of the present disclosure, the second output control module includes a first processing submodule and a second processing submodule, the first processing submodule receives the first power supply voltage and responds to the first clock signal and the second clock signal to output a first processing signal and a second processing signal, the first processing signal is applied to the first output control module, and the second processing signal is applied to the second processing submodule; the second processing submodule receives the second power supply voltage and responds to the first clock signal, the second clock signal, the second processing signal and an output of the input module to generate the second node voltage.

In some embodiments of the present disclosure, the first processing submodule includes a seventh switching transistor, an eighth switching transistor and a ninth switching transistor, a second terminal of the seventh switching transistor and a control terminal of the eighth switching transistor are connected to an output terminal of the input module, a control terminal of the seventh switching transistor receives the second clock signal, a first terminal of the seventh switching transistor is connected to a first terminal of the ninth switching transistor, a second terminal of the ninth switching transistor receives the first power supply voltage, a control terminal of the ninth switching transistor is connected to a first terminal of the eighth switching transistor, a second terminal of the eighth switching transistor receives the first clock signal, the first terminal of the eighth switching transistor outputs the first processing signal, and the second terminal of the seventh switching transistor outputs the second processing signal.

In some embodiments of the present disclosure, the second processing submodule includes a tenth switching transistor, an eleventh switching transistor and a twelfth switching transistor, a control terminal of the tenth switching transistor and a first terminal of the eleventh switching transistor are connected to an output terminal of the input module, a second terminal of the eleventh switching transistor is connected to the output module, a control terminal of the eleventh switching transistor receives the second power supply voltage, a first terminal of the tenth switching transistor is connected to a first terminal of the twelfth switching transistor, a second terminal of the tenth switching transistor receives the second clock signal, and a control terminal of the twelfth switching transistor receives the first clock signal, and the second terminal of the eleventh switching transistor outputs the second node voltage.

In some embodiments of the present disclosure, the output module includes a thirteenth switching transistor and a fourteenth switching transistor, a control terminal of the thirteenth switching transistor receives the first node voltage, a first terminal of the thirteenth switching transistor receives the first power supply voltage, a second terminal of the thirteenth switching transistor is connected to a first terminal of the fourteenth switching transistor, a control terminal of the fourteenth switching transistor receives the second node voltage, a second terminal of the fourteenth switching transistor receives the second power supply voltage, and a common node of the second terminal of the thirteenth switching transistor and the first terminal of the fourteenth switching transistor outputs the light-emitting control signal.

In some embodiments of the present disclosure, the output module further includes a second capacitor, a first plate of the second capacitor is connected to the control terminal of the fourteenth switching transistor, and a second plate of the second capacitor is connected to the second output control module.

In some embodiments of the present disclosure, the output module further includes a third capacitor, a first plate of the third capacitor is connected to the control terminal of the thirteenth switching transistor, and a second plate of the third capacitor receives the first power supply voltage.

In some embodiments of the present disclosure, the first clock signal and the second clock signal have a same frequency, and there is a phase difference between the second clock signal and the first clock signal.

In some embodiments of the present disclosure, switching transistors of each of the stages are positive channel metal oxide semiconductor (PMOS) transistors.

Another aspect of the present disclosure provides a display apparatus, including the display panel according to any one of the above embodiments.

According to a technical solution of the present disclosure, the display panel includes a pixel circuit, the pixel circuit includes a driving transistor, a light-emitting control transistor and a light-emitting device. A first electrode of the driving transistor is electrically connected to a power supply voltage terminal, and a second electrode of the driving transistor is electrically connected to a first electrode of the light-emitting control transistor. A second electrode of the light-emitting control transistor is electrically connected to an electrode of the light-emitting device, and a gate of the light-emitting control transistor is connected to a light-emitting control signal line to receive a light-emitting control signal transmitted by the light-emitting control signal line. In one cycle of the light-emitting control signal, the light-emitting control signal includes a plurality of pulses, one of the pulse includes one non-enable level and one enable level adjacent to each other, the pulses of the light-emitting control signal include a first pulse and a second pulse, a non-enable level duration of the first pulse is S1, a non-enable level duration of the second pulse is S2, and S1>S2. A reference refresh frequency of the display panel is F0, in a first display mode, one picture refresh frame of the display panel includes a data writing frame, a frequency of the light-emitting control signal in the data writing frame is F1, and F1>F0. The technical solutions of the present disclosure solve the problem in the prior art that for display screens with low base frequencies, the unequal width design of the light-emitting control signal is prone to causing flickering to be perceived by the human eye, by setting the non-enable level durations of the first pulse and the second pulse in the light-emitting control signal, and setting the frequency of the light-emitting control signal in the data writing frame to be higher than the reference refresh frequency.

### BRIEF DESCRIPTION OF DRAWINGS

The drawings constituting a part of the present disclosure are used to provide further comprehension of the present disclosure. Exemplary embodiments of the present disclosure and the descriptions thereof are used to explain the present disclosure and do not constitute an improper limitation to the present disclosure. In the drawings:

FIG. 1 is a circuit structural schematic diagram of a pixel circuit of a display panel according to an embodiment of the present disclosure;

FIG. 2 is a schematic diagram of a light-emitting control signal of a pixel circuit of a display panel according to an embodiment of the present disclosure;

FIG. 3 is a schematic diagram of a light-emitting control signal of a pixel circuit of a display panel when a reference refresh frequency is 60 Hz according to an embodiment of the present disclosure;

FIG. 4 is a schematic diagram of a light-emitting control signal of a pixel circuit of a display panel when a reference refresh frequency is 45 Hz according to an embodiment of the present disclosure;

FIG. 5 is a schematic diagram of a light-emitting holding frame of a light-emitting control signal of a pixel circuit of a display panel according to an embodiment of the present disclosure;

FIG. 6 is a schematic diagram of various signals of a pixel circuit of a display panel according to an embodiment of the present disclosure;

FIG. 7 is a circuit structural schematic diagram of a driving circuit of a display panel according to an embodiment of the present disclosure;

FIG. 8 is a circuit structural schematic diagram of two stages of a light-emitting driver of a display panel according to an embodiment of the present disclosure;

FIG. 9 is a time sequence design diagram of a light-emitting control signal of a driving circuit of a display panel according to an embodiment of the present disclosure;

FIG. 10 is a circuit structural schematic diagram of a driving circuit of a further display panel according to an embodiment of the present disclosure;

FIG. 11 is a circuit structural schematic diagram of a driving circuit of a further display panel according to an embodiment of the present disclosure; and

FIG. 12 is a schematic diagram of a display apparatus according to an embodiment of the present disclosure.

The drawings include the following reference signs: 10—input module; 20—first output control module; 30—second output control module; 301—first processing submodule; 302—second processing submodule; 40—output module; 100—display panel.

### DESCRIPTION OF EMBODIMENTS

It should be noted that the following detailed descriptions are exemplary and aims at providing further explanation of the present disclosure. Unless otherwise specified, all technical and scientific terms used herein have the same meaning as commonly understood by those skilled in the art to which the present disclosure belongs.

It should be noted that the terms used herein are just for describing specific implementations, and are not intended to limit the exemplary implementations according to the present disclosure. As used herein, unless explicitly stated in the context, the singular form is also intended to include the plural form. In addition, it should be understood that the terms “comprising” and/or “including”, when used in the specification, indicates the presence of features, steps, operations, devices, assemblies, and/or any combination thereof.

It should be noted that the orientation or positional relationships indicated by the terms “up”, “down”, “left”, “right”, etc. are the orientation or positional relationships shown in the drawings, which are just for the convenience of description, and do not indicate or imply that the device or element referred to must have a specific orientation, be constructed and operated in specific orientation, and thus should not be understood as limitations to the present disclosure. The terms “first” and “second” are just used for descriptive purposes and cannot be understood as indicating or implying relative importance or implicitly indicating the number of technical features. “A plurality of” means two or more, unless otherwise clearly and specifically defined. In addition, the terms “horizontal”, “vertical”, and “overhanging”, etc. do not imply that the components are required to be absolutely horizontal or overhanging, but can be slightly tilted. For example, “horizontal” only means that the direction is more horizontal relative to “vertical”, which does not mean that the structure must be completely horizontal, but can be slightly tilted.

It should also be noted that, unless otherwise clearly specified and defined, the terms “set”, “mount”, “join”, and “connect” should be understood in a broad sense, for example, can be a fixed connection, a detachable connection, or an integral connection; or can be a mechanical connection, or an electrical connection; or can be a direct connection, or an indirectly connection through an intermediate medium, or an internal communication of two elements. For those skilled in the art, the specific meanings of the above terms in the present disclosure can be understood according to specific circumstances.

In order to illustrate the technical solution of the present disclosure, a detailed explanation will be provided below in conjunction with the drawings and embodiments.

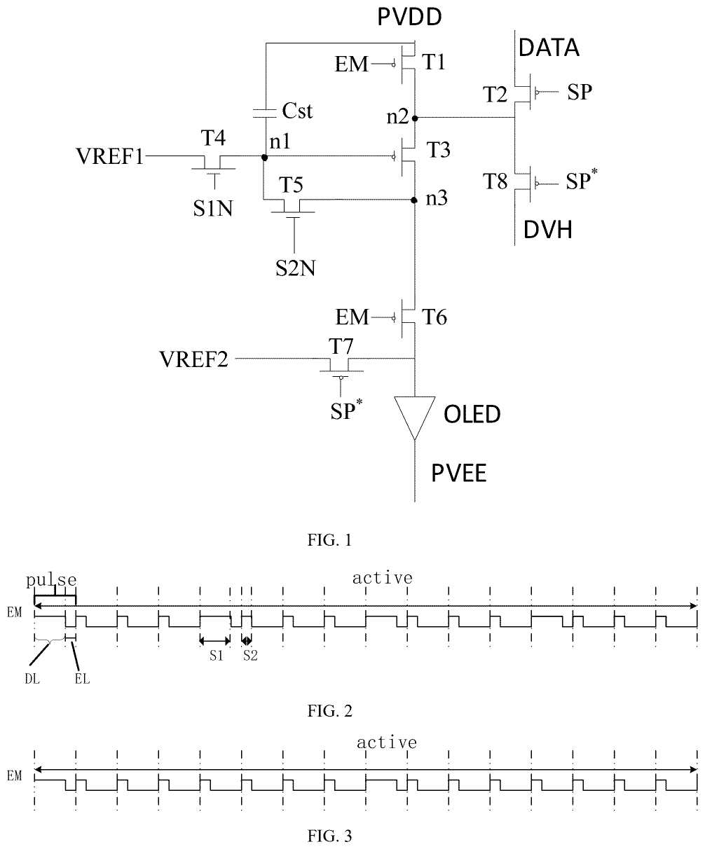

An embodiment of the present disclosure provides a display panel. The display panel includes a pixel circuit. FIG. 1 is a circuit structural schematic diagram of a pixel circuit of a display panel according to some embodiments of the present disclosure. As shown in FIG. 1, the pixel circuit includes a driving transistor T3, a light-emitting control transistor T6 and a light-emitting device, Organic Light-Emitting Diode (OLED). A first electrode of the driving transistor T3 is electrically connected to a power supply voltage terminal PVDD, and a second electrode of the driving transistor T3 is electrically connected to a first electrode of the light-emitting control transistor T6. A second electrode of the light-emitting control transistor T6 is electrically connected to an electrode of the light-emitting device OLED, and a gate of the light-emitting control transistor T6 is connected to a light-emitting control signal line to receive a light-emitting control signal EM sent by the light-emitting control signal line. As shown in FIG. 2, in one cycle of the light-emitting control signal, the light-emitting control signal includes a plurality of pulses pulse, one pulse includes one non-enable level stage DL and an enable level stage EL that are adjacent to each other, the pulses of the light-emitting control signal include a first pulse and a second pulse, a non-enable level duration of the first pulse is S1, a non-enable level duration of the second pulse is S2, and S1>S2. A reference refresh frequency of the display panel is F0, in a first display mode, one picture refresh frame of the display panel includes a data writing frame, a frequency of the light-emitting control signal in the data writing frame is F1, and F1>F0. In some embodiments of the present disclosure, the electrical connection between the first electrode of the driving transistor T3 and the power supply voltage terminal PVDD can be an electrical connection between the first electrode of the driving transistor T3 and the power supply voltage terminal PVDD achieved by turning on a transistor T1, or can be an electrical connection achieved by other methods, as long as the first electrode of the driving transistor T3 can be electrically connected to the power supply voltage terminal PVDD at least at a certain moment to transmit signals.

In some embodiments of the present disclosure, the display panel according to the embodiments of the present disclosure can adopt organic light-emitting diode (OLED) technology, of which the basic component unit is a pixel circuit configured to control the light-emitting state of each pixel. Each pixel circuit includes: a driving transistor (for controlling current), a light-emitting device (OLED unit) and a light-emitting control transistor connected in series between the driving transistor and the light-emitting device. It should be understood that the display panel of the present disclosure can also adopt a micro light-emitting diode (micro LED), a light-emitting diode (LED) display panel or other types.

Driving transistor: the first electrode thereof (generally the source or drain, depending on the circuit design) is electrically connected to the power supply voltage terminal to receive the power supply voltage; and the second electrode thereof is electrically connected to the first electrode (also the source or drain) of the light-emitting control transistor. The second electrode of the light-emitting control transistor is connected to an electrode of the light-emitting device to control whether the driving current flows to the OLED unit, so as to control the light-emitting state of the OLED unit. The light-emitting control signal line is connected to the gate of the light-emitting control transistor to transmit a control signal, which determines whether the light-emitting control transistor is turned on or off, and thus control the light-emitting state of the OLED unit.

An enable level of the light-emitting control signal refers to the level that controls the corresponding transistor to be turned on, and a non-enable level refers to the level that controls the corresponding transistor to be turned off. When the light-emitting control transistor is a P-type transistor, the enable level of the light-emitting control signal means a low level, and the non-enable level means a high level. In one cycle, the light-emitting control signal includes a plurality of pulses and each of the plurality of pulses consists of a non-enable level (a high level when the light-emitting control transistor is a P-type transistor) and an adjacent enable level (a low level when the light-emitting control transistor is a P-type transistor).

The pulses of the light-emitting control signal include two types of pulses, namely, a first pulse and a second pulse, that is, the pulses of the light-emitting control signal include a plurality of first pulses and a plurality of second pulses, and the main difference between them is that the non-enable level durations are different. The non-enable level duration of the first pulse is S1, the non-enable level duration of the second pulse is S2, and the non-enable level duration S1 of the first pulse is greater than the non-enable level duration S2 of the second pulse.

The inventor of the present disclosure has found through research that when a light-emitting control signal is configured to adopt a multi-pulse design, since the pixel circuit has operating stages such as data signal writing and threshold capture, the non-enable level duration of the first pulse of the light-emitting control signal will be set longer, and the non-enable level durations of the second and subsequent pulses will be set shorter. That is, the enable level durations in one cycle of a light-emitting control signal will be different. For the display screen with a high fundamental frequency, such as 120 Hz, the unequal width of the light-emitting control signal is not prone to being perceived by the human eye. In contrast, for some display screens with a low fundamental frequency, such as 60 Hz or 45 Hz, the unequal width design is prone to causing flickering to be perceived by the human eye. The design of the present disclosure can reduce the flickering effect by adjusting the duration of the pulse of the light-emitting control signal, especially during the data writing frame. During a general data writing process, the long non-enable level duration is related to data writing and signal transmission, and after the data writing is completed, it can increase the effective light-emitting time of the OLED unit and adjust the display brightness by shortening the non-enable level duration.

The reference refresh frequency F0 is the frequency at which the display panel updates the picture in normal display mode, measured in Hertz (Hz). It directly affects the smoothness of the display, the response speed, and the possible flicker perception. A high refresh frequency generally means a smooth display effect and less motion blur. In some embodiments of the present disclosure, the reference refresh frequency F0 of the display panel satisfies F0≤90 Hz, that is, by limiting the application of the technology to display panels with a frequency of 90 Hz or below, the inventiveness and practicality of the technical solution of the present disclosure are emphasized in low to medium refresh frequency scenarios. The technical effect of the present disclosure is more obvious in the panels with a low fundamental frequency, and the applicable scenarios of the present disclosure are further refined, especially 60 Hz and 45 Hz as two typical refresh frequencies. 60 Hz is the refresh frequency of many standard monitors and laptops, while 45 Hz is even lower and may appear in specific low-power display devices, such as some electronic ink screen devices. This specific refresh frequency range highlights the optimization role of the present disclosure in these common low refresh frequency applications, especially for display panels with refresh frequencies of 60 Hz and 45 Hz, which can significantly reduce the flicker problem caused by unequal width pulses of the light-emitting control signal.

In the first display mode, a picture refresh frame (also known as a frame cycle) of the display panel includes a data writing frame. The frame is calculated based on the minimum cycle of a light-emitting stage, and the data writing frame starts from the writing time of the first row of pixel data in the first frame and ends at the writing time of the last row of pixel data in the first frame. At this time, the frequency F1 of the light-emitting control signal is higher than the reference refresh frequency F0. This means that during the data writing frame, the pulse frequency of the light-emitting control signal will increase, so as to increase the frequency of the pulse appearance of the light-emitting control signal, improve the flicker problem at low frequencies, and make it difficult for the human eye to perceive flicker.

Overall, the visual quality of the display panel is improved by adjusting the pulse time sequence and frequency of the light-emitting control signal, especially during the data writing frame, and in particular, in the low refresh frequency mode. The pulse frequency of the light-emitting control signal is increased to be higher than the flicker threshold that can be detected by the human eye, so as to significantly reduce the flicker phenomenon, and provide a smoother and more comfortable viewing experience.

In one cycle of a light-emitting control signal, the number of the first pulses of the light-emitting control signal is N1, and the number of the second pulses is N2. N2=k1×N1, where k1 is a positive integer, and k1≥2. Referring to FIG. 2, N1=4, and N2=12.

The light-emitting control signal is a signal that controls whether the pixel in the light-emitting device emits light, which will experience multiple on and off times in a complete operating cycle, that is, it will experience multiple conversions from the non-enable level (a high level is used as an example to indicate on in an embodiment of the present disclosure) to the enable level (a low level is used as an example to indicate off in an embodiment of the present disclosure,). The pulse sequence and duration of the signal in this cycle determine the light-emitting duration and intensity of the pixel, so as to affect the display effect of the entire display panel.

In one cycle of the light-emitting control signal, the number of the first pulses is N1, and the number of the second pulses is N2. The number of the second pulses is k1 times the number of the first pulses, where k1 is a positive integer, and k1≥2, which means that in each cycle, the number of the second pulses is at least twice the number of the first pulses. This design is to ensure that after the data is written, there are more pulses used to control the light emission of the pixels, so as to increase the light-emitting time overall and reduce the flicker caused by uneven width of the pulses (especially under a condition with a low refresh frequency).

Through the above design, even at a low refresh frequency, such as 60 Hz or lower, the effective frequency of the light-emitting control signal will be increased due to the increase in the number of the second pulses, so that the cycle frequency between two adjacent identical pulses (i.e., the second pulses) is greater than 60 Hz. This can take advantage of the fact that the human eye cannot perceive the flicker at the frequencies higher than 60 Hz, so as to significantly improve the display effect and provide smooth, flicker-free viewing experience.

By setting non-enable level pulses with different lengths in the light-emitting control signal and ensuring that the number of the second pulses is at least twice the number of the first pulses, this technology can increase the refresh frequency of the display panel at a low refresh frequency to reduce visible flicker and optimize the visual effect.

FIG. 2 is just an exemplary representation. In FIG. 2, there are 16 pulses in one cycle of the light-emitting control signal. In other implementations, there may be 32 pulses in one cycle of the light-emitting control signal. For example, N1=4 and N2=28.

Furthermore, the number N1 of the first pulses is negatively correlated with the reference refresh frequency F0, and the number N2 of the second pulses is positively correlated with the reference refresh frequency F0.

That is, the total number of the pulses in one cycle of the light-emitting control signal is constant. For different reference refresh frequencies, if it is desired that the flicker is not easily to be perceived by the human eye under the adjusted refresh frequency, the higher the reference refresh frequency is, the fewer the number of the first pulses and the more the number of the second pulses are. On the contrary, the lower the reference refresh frequency is, the more the number of the first pulses and the fewer the number of the second pulses are.

It should be noted that the number of the first pulses should not be set too many, as long as the flicker is not easily perceived by the human eye under the adjusted refresh frequency. The control of the light-emitting time needs to be considered simultaneously, that is, the number of the second pulses should not be too small.

In some embodiments of the present disclosure, the number N1 of the first pulses is negatively correlated with the reference refresh frequency F0, that is, as the reference refresh frequency increases, the number of the first pulses decreases; and as the reference refresh frequency decreases, the number of the first pulses increases. It takes a certain amount of time to display each frame (i.e., picture), and the length of this time period is directly related to the refresh frequency of the display panel (reference refresh frequency). The higher the refresh frequency, the shorter the display time of each frame, and vice versa. The first pulse is usually closely related to the data writing process, that is, at the beginning of each frame, a long pulse width of the light-emitting control signal is required to support the data writing of the pixel circuit.

After the data writing is completed, the second pulse is used to control the light emission of the pixel, which usually has a short non-enable level duration, so as to increase the light-emitting time. Under the conditions with a high refresh frequency, since the display time of each frame is short, in order to fully display the picture, it is necessary to quickly perform multiple times of light-emitting controls in each frame. This means that more second pulses are needed. Therefore, the number of the second pulses will increase with the increase of the reference refresh frequency, thereby forming a positive correlation. Under the conditions with a low refresh frequency, the display time of each frame is longer, and it takes fewer second pulses to control the light emission without sacrificing the display effect, thus the number of the second pulses will decrease with the decrease of the refresh frequency.

Overall, this design is used to improve display quality, especially to reduce flicker phenomenon that may occur at low refresh frequencies, such as 60 Hz or lower. By adjusting the number of the first pulses and the second pulses in the light-emitting control signal, the processes of data writing and light-emitting control can be optimized, and the smoothness of the display effect and the reduction of flicker can be ensured even under a condition with a low refresh frequency, so as to provide a better visual experience. This mechanism can dynamically adjust the pulse sequence of the light-emitting control signal in application scenarios with different refresh frequencies, so as to increase the effective light-emitting time and reduce the flicker that can be perceived by the human eye while ensuring data transmission efficiency.

FIG. 3 is a schematic diagram of a light-emitting control signal when the reference refresh frequency is 60 Hz. As shown in FIG. 3, there are two first pulses (long non-enable level duration) of the light-emitting control signal. The number of the first pulse is set to be two, which means that the number of subsequent second pulses (short non-enable level duration) is k1 times the number of the first pulse, where k1 is usually a positive integer and at least 2. Therefore, in FIG. 3, if there are two first pulses, the number of the second pulses is at least 4, so that the cycle frequency between the first pulse and the subsequent identical pulse reaches 120 Hz, which is higher than the reference refresh frequency of 60 Hz, so as to reduce flicker.

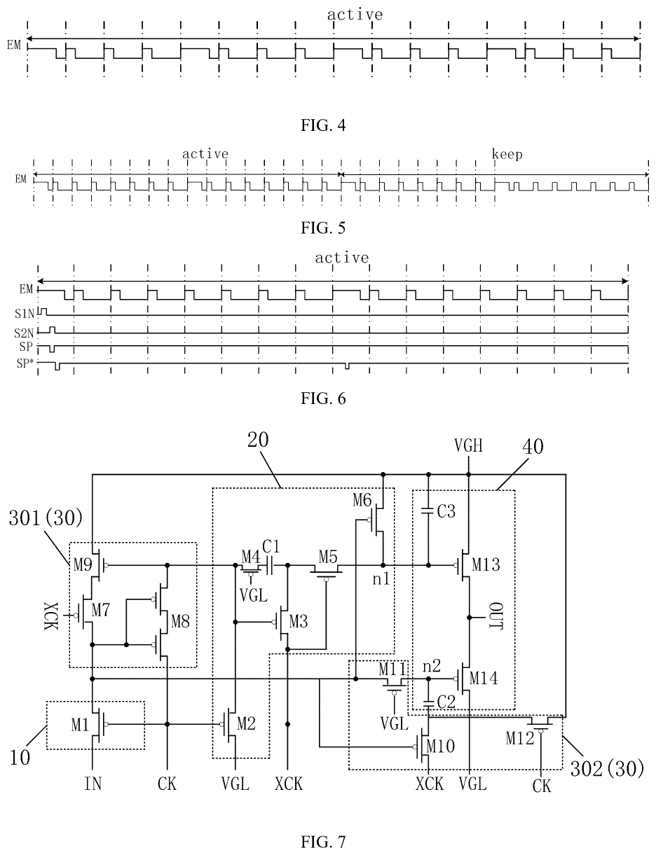

Similarly, FIG. 4 is a schematic diagram of a light-emitting control signal when the reference refresh frequency is 45 Hz. As shown in FIG. 4, the number of the first pulses (long non-enable level duration) of the light-emitting control signal is four, following the same multiple relationship, and if the number of the first pulses is four, the number of the second pulses is at least twice the first pulses, that is, at least 8. In this way, the cycle frequency between the first pulse and the subsequent identical pulses can reach 180 Hz, which is also higher than the reference refresh frequency, so as to achieve the effect of reducing flicker at a refresh frequency of 45 Hz.

The possibility of the human eye recognizing flicker above 60 Hz is greatly reduced. Based on this characteristic, by adding the same or similar light-emitting control signal pulses within a picture refresh frame of the display panel, the frequency of these pulses is higher than the recognition threshold of the human eye, that is, higher than 60 Hz, which can significantly improve the display effect and reduce or eliminate the flicker that can be perceived by the human eye. Under the condition with a low refresh frequency, such as 45 Hz, by increasing the number of the first pulses and meanwhile reducing the number of the second pulses, it is possible to ensure that the cycle frequency of the light-emitting control signal pulses is higher than 60 Hz, so as to provide a smooth and flicker-free display effect at even a low refresh frequency.

In summary, FIG. 3 and FIG. 4 show how to adjust the pulse structure of the light-emitting control signal according to different reference refresh frequencies to optimize the display effect and reduce the flicker that can be perceived by the human eye. By increasing the number of the first pulses, and increasing the number of the second pulses according to a specific ratio, it can be ensured that the cycle frequency of the light-emitting control signal pulse is higher than the threshold of flicker that can be recognized by the human eye, so as to provide a better visual experience. In application scenarios with different refresh frequencies, this mechanism can dynamically adjust the pulse sequence of the light-emitting control signal, optimize the data writing and light-emitting control processes, reduce flicker, and improve display quality.

It can be understood that one cycle of the light-emitting control signal includes a plurality of groups of pulses, and any group of the pulses includes one first pulse and a plurality of second pulses subsequent to the first pulse.

In a complete cycle of the light-emitting control signal, the signal is divided into a plurality of groups of pulses (which can be understood as a plurality of subsequences), each group of the pulses includes a specific combination of the first pulse and the second pulse. This grouping strategy allows for more refined control, which can adjust the pulse combination under different operating conditions (such as different refresh frequencies) to achieve the best display effect.

As shown in FIG. 2, the signal is divided into four groups of pulses. In any group of the pulses, firstly, there is one the first pulse, which has a long non-enable level duration, mainly configured to support data writing and signal processing. Subsequent to the first pulse, There are three second pulses, which have non-enable level durations, mainly configured to control the pixel light emission. The number of these second pulses is k1 times the first pulse, k1 is a positive integer and at least 2. This design ensures that after the data writing is completed, sufficient effective light-emitting time is guaranteed, so as to reduce the flickering feeling while ensuring the display effect.

By setting a plurality of groups of pulses including the first pulse and the second pulse in one cycle, the cycle frequency of the signal can be adjusted so that the cycle frequency from the first pulse to the next identical first pulse is higher than the frequency of flicker that can be recognized by the human eye, which is usually higher than 60 Hz. Even under a condition with a low refresh frequency, this design can ensure that the cycle frequency of the signal is high enough, so as to significantly improve display quality and reduce flicker.

In this way, the technical solution of the present disclosure can improve the visual comfort of the display panel without sacrificing data writing efficiency, especially in low refresh frequency application scenarios, such as 60 Hz or lower refresh frequencies, so as to provide smooth and flicker-free viewing experience.

Furthermore, in the first display mode, one picture refresh frame of the display panel further includes M light-emitting holding frames, where M≥1. In the light-emitting holding frames, the frequency of the light-emitting control signal is F1.

In some embodiments of the present disclosure, the display panel can have multiple display modes, which can be adjusted based on different performance requirements or application scenarios. In one picture refresh frame, one time of picture update completed by the display panel includes data writing and actual display time. As shown in FIG. 5, in the first display mode, in addition to the data writing frame, one picture refresh frame further includes M light-emitting holding frames keep, where M is at least 1.

The light-emitting holding frame is a series of frames configured to maintain the brightness of the display picture after the data writing is completed. In the part of the frames, the frequency of the light-emitting control signal is still set to be F1, which is already mentioned in the data writing frame and is higher than the reference refresh frequency of the display panel. By holding the high frequency of the light-emitting control signal in the light-emitting holding frames, it can be ensured that the light-emitting control of the pixel is smoother when displaying the picture, so as to reduce the flicker phenomenon caused by the low signal frequency, and provide more continuous and stable display effect.

The light-emitting control signal plays a key role in driving the display panel, which determines when the pixel circuit starts to emit light and the light-emitting duration. In the first display mode, by optimizing the pulse structure of the light-emitting control signal in the data writing frame and maintaining the high frequency F1 of the light-emitting control signal in the subsequent M light-emitting holding frames, it can be ensured that even under a condition with a low refresh frequency, a flicker frequency that is not easily perceived by the human eye can be achieved. This optimization strategy is particularly aimed at situations where the reference refresh frequency is low, such as 60 Hz or 45 Hz. By increasing the frequency of the light-emitting control signal, the cycle frequency of the signal is greater than 60 Hz, so as to significantly improve the display effect, and reduce or eliminate flicker that can be perceived by the human eye.

By introducing the light-emitting holding frames in the first display mode and maintaining the high frequency of the light-emitting control signal in these frames, the present disclosure can dynamically adjust the frequency and pulse structure of the light-emitting control signal according to different display modes and refresh frequency requirements, to achieve the best display effect. This dynamic adjustment mechanism can improve the display smoothness and visual comfort without affecting the data writing efficiency, especially in the low refresh frequency mode, so as to provide a higher-quality display experience.

In summary, embodiments of the present disclosure provide technical solutions that in the first display mode, the display effect is optimized and flicker is reduced by adding light-emitting holding frames to the picture refresh frames and maintaining the high frequency of the light-emitting control signal in these frames, to optimize the display effect and reduce the flicker phenomenon. This design achieve the display effect that flicker will not be easily detected by the human eye even at low refresh frequencies by increasing the frequency of the light-emitting control signal, so as to provide more continuous and smoother viewing experience.

Furthermore, F1=k2×F0, where k2 is a positive integer, and k2≥2.

The frequency F1 of the light-emitting control signal should be k2 times the reference refresh frequency F0, where k2 is a positive integer and k2≥2. This means that the frequency of the light-emitting control signal is at least twice the reference refresh frequency. For example, when the reference refresh frequency F0 is 60 Hz, the frequency F1 of the light-emitting control signal is at least 120 Hz. In some embodiments of the present disclosure, as shown in FIG. 4, when the reference refresh frequency F0 is 45 Hz, and k2 is 4, the frequency F1 of the light-emitting control signal satisfies F1=4×45=180 Hz.

The purpose of this design is to reduce or eliminate flicker phenomenon at low refresh frequencies, such as 60 Hz or lower, and to improve the visual comfort of the display effect. The human eye's perception of flicker at frequencies above 60 Hz is significantly reduced. Therefore, by increasing the frequency of the light-emitting control signal to at least twice the reference refresh frequency, it can be ensured that during the light-emitting holding frames, the switching frequency of the signal is high enough to make the flicker almost imperceptible to the human eye, so as to provide a smooth and natural display effect. The flicker phenomenon is usually caused by the mismatch between the signal frequency and the refresh frequency of the display panel. Under a condition with a low refresh frequency, if the frequency of the light-emitting control signal is also low, the cyclical changes of the signal may be captured by the human eye, thereby resulting in a sense of flicker. In some embodiments of the present disclosure, by increasing the frequency of the light-emitting control signal to at least twice the reference refresh frequency and utilizing the visual fusion effect of fast pulse switching, the display effect can achieve high continuity and stability even in low refresh frequency mode, so as to greatly reduce the perception of flicker.

By setting the multiple relationship between the frequency F1 of the light-emitting control signal and the reference refresh frequency F0, an embodiment of the present disclosure provide a flexible display optimization solution. In display modes with different refresh frequencies, by adjusting the value of k2 alone, different display requirements can be adapted to ensure that a low-flicker display effect can be achieved in any mode, whether in standard refresh frequency mode or low power consumption mode, and provide a user-friendly visual experience.

In summary, the technical point of these embodiment is that by setting the frequency F1 of the light-emitting control signal in the light-emitting holding frames to at least twice the reference refresh frequency F0, and utilizing the fact that the human eye is insensitive to high-frequency changes, the flicker phenomenon of the display panel at low refresh frequencies is significantly reduced, so as to provide a smooth and comfortable viewing experience. This design not only optimizes the display effect, but also enhances the adaptability and flexibility of the display panel in different refresh frequency modes.

Furthermore, S1=k3×S2, where k3 is a positive integer, and k3≥2.

The light-emitting control signal controls the light-emitting state of the pixel through cyclical pulses. The width of the pulses is crucial to the control effect. The first pulse is usually closely related to the data writing process, and has a long non-enable level duration S1 to ensure accurate data writing. The second pulse is a pulse configured to control the pixel light emission after the data writing is completed, and has a short non-enable level duration S2 to increase the effective light-emitting time.

In some embodiments of the present disclosure, the non-enable level duration S1 of the first pulse is k3 times the non-enable level duration S2 of the second pulse, where k3 is a positive integer, and k3≥2. This means that the non-enable level duration of the first pulse is at least twice the non-enable level duration of the second pulse. For example, as shown in FIG. 2, the non-enable level duration of the first pulse is four times the non-enable level duration of the second pulse. If the non-enable level duration S2 of the second pulse is 2 microseconds, the non-enable level duration S1 of the first pulse is 8 microseconds.

The ratio of the non-enable level duration of the first pulse to the non-enable level duration of the second pulse is set to optimize the display effect of the display panel in different operation modes. The first pulse is usually at the beginning of the signal cycle and is closely related to the data writing process, which requires sufficient time to ensure that the data is accurately written into the pixel circuit. The second pulse appears after the data is written, and is mainly used to control the light-emitting state of the pixel. By setting the non-enable level duration S1 of the first pulse to at least twice the non-enable level duration S2 of the second pulse, the effective light-emitting time can be increased while ensuring the data writing efficiency, and the flicker phenomenon caused by the cyclical changes of the signal can be reduced, so as to provide a more continuous and stable display effect. The root cause of the flicker phenomenon is that the cyclical changes of the signal does not match the display refresh frequency, causing the human eye to be able to detect the fluctuation of the brightness. By increasing the non-enable level duration ratio of the first pulse to the non-enable duration ratio of the second pulse, the cycle of the signal can be adjusted to ensure that even under a condition with a low refresh frequency, the cycle frequency of the signal is high enough, so that flicker is not easily detected by the human eye. At the same time, by setting a plurality of short second pulses after the data writing frame, it can be ensured that the pixel has enough time to emit light in the enable level state, so as to increase the effective light-emitting time and reduce the flickering feeling.

By setting a specific ratio of the non-enable level duration of the first pulse to the non-enable level duration of the second pulse, in different refresh frequencies or display modes, only the value of k3 needs to be adjusted to meet various brightness, contrast and refresh frequency requirements without major modifications to the hardware circuit. This mechanism enables the display panel to flexibly achieve the best display effect under different operating conditions, especially in low refresh frequency mode, and can reduce flicker and improve the viewing experience.

Referring to FIG. 1, the pixel circuit further includes a data writing transistor T2 and a bias adjusting transistor T8. A first electrode of the data writing transistor T2 is electrically connected to a data line to receive a data signal DATA. A second electrode of the data writing transistor T2 is electrically connected to the first electrode of the driving transistor T3 to write a data voltage to a gate of the driving transistor to control the light-emitting intensity of the pixel. A first electrode of the bias adjusting transistor T8 is electrically connected to the first electrode of the driving transistor T3, and a second electrode of the bias adjusting transistor T8 is electrically connected to a bias adjusting signal line to receive a bias adjusting signal DVH. A gate of the bias adjustment transistor T8 is electrically connected to the first scanning signal line to receive the first scanning signal SP*. The function of the bias adjustment transistor is to adjust the bias voltage of the pixel circuit to compensate for the influence of various environmental factors (such as temperature changes, power supply voltage fluctuations, etc.) on the display effect. The data is written into the frame, the number of cycles of the light-emitting control signal EM is N, and N≥2. As shown in FIG. 6, a pulse of the first scanning signal SP* includes an enable level stage and a non-enable level stage. The enable level of the first scanning signal SP* overlaps with the non-enable level of the first pulse of the light-emitting control signal EM.

In some embodiments of the present disclosure, in the data writing frame, the number of cycles N of the light-emitting control signal is at least 2. This means that in each cycle of the data writing frame, the light-emitting control signal will undergo at least two alternations of enable and non-enable levels to control the light-emitting state and cycle of the pixel. Each wide light-emitting control signal EM corresponds to the first scanning signal SP* being turned on, which corresponds to the frequency of the first scanning signal SP* being increased accordingly. In some implementations, the starting moment of the enable level of the first scanning signal SP* is after the starting moment of the non-enable level of the first pulse of the light-emitting control signal EM, and the ending moment of the enable level of the first scanning signal SP* is before the ending moment of the non-enable level of the first pulse of the light-emitting control signal EM. If there are N cycles of the light-emitting control signal in the data writing frame, there are N first pulses, and the corresponding first scanning signal SP* also has N enable level stages.

A pulse of the first scanning signal includes an enable level and a non-enable level. The enable level is used to activate the bias adjustment transistor and the data writing transistor for data writing and bias voltage adjustment. The non-enable level indicates the off state of the transistor, which is used to stop data writing and bias voltage adjustment. In the data writing frame, there is an overlapping time period between the enable level of the first scanning signal and the non-enable level of the first pulse of the light-emitting control signal. The purpose of this overlapping design is to ensure that the data writing transistor and the bias adjustment transistor are activated at the same time during the data writing process, to ensure that the data can be accurately written into the driving transistor, and to adjust the bias voltage, so as to ensure the stable operation of the pixel circuit and consistent display effect.

The above design improves the display quality and efficiency of the display panel under different conditions. The coordinated operation of the data writing transistor and the bias adjustment transistor enables accurate data writing and fine bias voltage adjustment even under complex environmental conditions. The number of cycles N of the light-emitting control signal satisfies N≥2 and the overlap with the enable level of the first scanning signal ensure that while controlling the light-emitting state of the pixel, effective data writing and bias voltage adjustment are also performed, which improves the continuity and stability of the display and reduces the flicker phenomenon caused by cyclical changes of the signal. This optimization is not only applicable to displays under standard refresh frequency conditions, but especially at low refresh frequencies, such as 60 Hz or lower. By ensuring the efficient completion of data writing and bias adjustment, the clarity and smoothness of the display can be further improved, flicker can be reduced, and a comfortable and natural viewing experience can be provided. By finely adjusting the signal interaction in the pixel circuit, the control of the light-emitting control signal is effectively optimized, and the accuracy of data writing and the consistency of the display effect are improved.

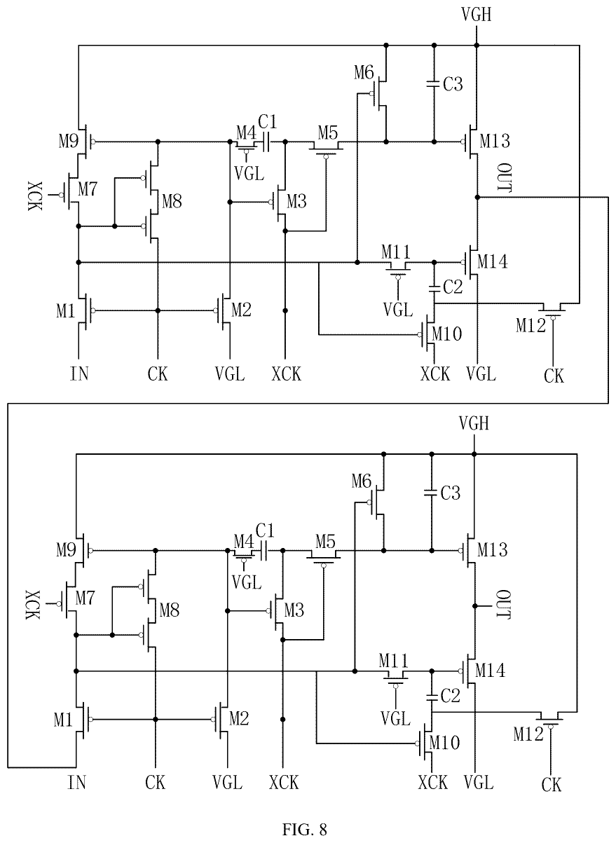

The display panel according to an embodiment of the present disclosure further includes a driving circuit, and the driving circuit of the display panel is configured for controlling the display operation of the pixels on the panel, including data writing, brightness adjustment and refresh control, etc. A light-emitting driver is the core part of the driving circuit, which generates a signal for controlling whether the pixel emits light, i.e., light-emitting control signal. FIG. 7 shows a circuit structural schematic diagram of a driving circuit of a display panel according to some embodiments of the present disclosure. The driving circuit includes a light-emitting driver, and the light-emitting driver is configured to generate the light-emitting control signal, and includes a plurality of stages. FIG. 8 shows a circuit structural schematic diagram of two stages of a light-emitting driver. The light-emitting driver adopts a multi-stage cascade design inside, and each stage receives a specific input signal and a control signal to generate a final light-emitting control signal. This cascade structure facilitates stably transmit and amplify the signal, ensuring that each pixel can receive an accurate control signal. Referring to FIG. 8, the OUT signal output by the driver of the previous stage is used as the IN signal of the driver of the next stage. After being processed by the driver of the first stage, the signal is converted into an OUT signal. Subsequently, the OUT signal is used as the IN signal of the driver of the next stage and is processed again until the signal is transmitted to the most downstream of the driving circuit to form a signal transmission chain. This transmission method ensures the accuracy and synchronization of the signal.

Referring to FIG. 7, the input terminal IN of each of the plurality of stages receives an input signal, a first clock signal CK, a second clock signal XCK, a first power supply voltage VGH, and a second power supply voltage VGL, and outputs a light-emitting control signal at an output terminal OUT. Each of the stages includes an input module 10, a first output control module 20, a second output control module 30, and an output module 40. The input module receives and responds to the input signal and the first clock signal to output a stage transmission to the previous stage. The first output control module receives the first power supply voltage and the second power supply voltage, and generates a first node voltage in response to the first clock signal and the second clock signal. The second output control module receives the first power supply voltage and the second power supply voltage, and generates a second node voltage in response to the first clock signal and the second clock signal. The output module receives the first power supply voltage and the second power supply voltage, and generates the light-emitting control signal in response to the first node voltage and the second node voltage.

It should be noted that the first clock signal and the second clock signal have the same frequency, and there is a phase difference between the second clock signal and the first clock signal. The first clock signal and the second clock signal have the same frequency, which means that the cycles of the first clock signal and the second clock signal are the same, and their waveforms repeat the same modes in the same time period. The same frequency means that the first clock signal and the second clock signal have the same number of waveform repetitions per second, which is a prerequisite for ensuring that the two signals can coordinate with each other and operate synchronously in the circuit. There is a phase difference between the second clock signal and the first clock signal, and the phase difference refers to the time sequence difference between the two clock signals. Although the first clock signal and the second clock signal have the same frequency, their waveforms will not completely overlap in time, and instead, has a certain offset. The introduction of the phase difference is usually to meet the time sequence requirements of different parts of the circuit, or to achieve more sophisticated signal control. In the display driving circuit, by adjusting the phase difference between the first clock signal and the second clock signal, time-sharing processing of data can be achieved, or more precise control can be achieved in the signal generation process, such as in the generation of the pulse of the light-emitting control signal, to ensure the precise alignment and stable periodicity of the signal, and reduce the flicker and improve the display quality.

The use of phase difference is particularly critical in display driving circuit design. For example, when the display panel operates at a low refresh frequency, such as 60 Hz or 45 Hz, the generation of the light-emitting control signal and the periodicity thereof are crucial for reducing flicker. By adjusting the phase of the second clock signal relative to the first clock signal, the triggering timing of the switching transistor in the output module can be controlled to ensure that the generation of the light-emitting control signal matches the refresh frequency of the display panel, so as to avoid display quality problems caused by inconsistent time sequence of the signal.

Furthermore, as shown in FIG. 7, the input module 10 includes a first switching transistor M1, a control terminal of the first switching transistor M1 receives the first clock signal CK, a first terminal of the first switching transistor M1 receives the input signal, and a second terminal of the first switching transistor M1 is an output terminal.

In some embodiments of the present disclosure, in the input module, the first switching transistor plays the role of signal transmission and control. When receiving the control signal, the first switching transistor can control the flow of the signal according to the state of the input signal, so as to determine whether to transmit the signal to the subsequent circuit module. The control terminal (usually the gate) of the first switching transistor receives the first clock signal CK. The clock signal is an important signal for controlling the signal processing rhythm in the digital circuit, and it alternates between high level and low level at a predetermined frequency. When the first clock signal CK is at a low level, the first switching transistor is triggered to turn on. On the contrary, when the first clock signal CK is at a high level, the first switching transistor is closed. This mechanism ensures the precise opening and closing of the signal, so as to control the signal transmission. The first terminal of the first switching transistor (usually one of the source or drain) is connected to the input signal. The input signal can be the OUT signal from the driver of the previous stage, or the initialization signal sent by the control circuit, which carries information for controlling the display state of the pixel. When the first switching transistor is turned on, the input signal can be transmitted to the second terminal of the switching transistor through the first terminal, and further transmitted to the output terminal of the input module, so as to prepare for subsequent signal processing. The second terminal of the first switching transistor (usually the other terminal of the drain or source) is the output terminal of the input module, i.e., the interface for transmitting the signal to the subsequent circuit. When the first switching transistor is turned on under the control of the first clock signal, the input signal flows from the first terminal of the first switching transistor to the second terminal, and is finally transmitted to the subsequent signal processing module, such as the first output control module or the second output control module, for further processing and generating the required light-emitting control signal.

In the input module, the first switching transistor acts as a “gate” or “bridge” for the signal, and its state (on or off) is controlled by the first clock signal CK. When the first clock signal CK is at a low level, the first switching transistor is turned on to allow the input signal to pass through, flow from the first terminal to the second terminal of the first switching transistor, and then to the output terminal of the input module. Subsequently, the signal is transmitted to the downstream circuit of the input module, such as the first output control module, to generate a node voltage. When the first clock signal CK is at a high level, the first switching transistor is turned off to prevent the transmission of the signal and enter a state of waiting for the next clock cycle. This design ensures the precise control and timed transmission of the signal, and is the basis for the driving circuit to operate stably and accurately control the display panel.

In applications with low refresh frequencies of the display panel, such as 60 Hz or 45 Hz, by precisely controlling the on and off of the first switching transistor and the transmission of the input signal, the signal processing process can be optimized, signal delay and distortion can be reduced, so as to optimize the generation of the light-emitting control signal, reduce flicker phenomenon, and improve the display quality.

Referring to FIG. 7, the first output control module 20 includes a second switching transistor M2, a third switching transistor M3, a fourth switching transistor M4, a fifth switching transistor M5 and a sixth switching transistor M6. A control terminal of the second switching transistor M2 receives the first clock signal CK, a second terminal of the second switching transistor M2 and a control terminal of the fourth switching transistor M4 receive the second power supply voltage VGL, a first terminal of the second switching transistor M2 is connected to a control terminal of the third switching transistor M3 and a first terminal of the fourth switching transistor M4, respectively, a first terminal of the third switching transistor M3 is connected to a second terminal of the fourth switching transistor M4 and a first terminal of the fifth switching transistor M5, a second terminal of the third switching transistor M3 and a control terminal of the fifth switching transistor M5 receive the second clock signal XCK, a second terminal of the fifth switching transistor M5 is connected to a second terminal of the sixth switching transistor M6, a first terminal of the sixth switching transistor M6 receives the first power supply voltage VGH, a control terminal of the sixth switching transistor M6 is connected to the output terminal of the input module 10, and the second terminal of the sixth switching transistor M6 outputs the first node voltage through a first node n1.

In the first output control module, the first node voltage is generated by precise control of the first clock signal CK and the second clock signal XCK and in combination with the first power supply voltage VGH and the second power supply voltage VGL, as follows.

The control terminal of the second switching transistor M2 receives the first clock signal CK, which indicates that the on and off of the second switching transistor M2 is controlled by the first clock signal CK. The second terminal of the second switching transistor M2 and the control terminal of the fourth switching transistor M4 receive the second power supply voltage VGL, which means that when the second switching transistor M2 is turned on, the second power supply voltage VGL can be transmitted to the internal circuit. The first terminal of the second switching transistor M2 is connected to the control terminal of the third switching transistor M3 and the first terminal of the fourth switching transistor M4, and such a connection means that a signal path is formed between the second switching transistor M2, the third switching transistor M3 and the fourth switching transistor M4.

The first terminal of the third switching transistor M3 is connected to the second terminal of the fourth switching transistor M4 and the first terminal of the fifth switching transistor M5, and the second terminal of the third switching transistor M3 and the control terminal of the fifth switching transistor M5 receive the second clock signal XCK. In the connection mode of the third switching transistor M3 and the fourth switching transistor M4, the second clock signal can cooperate with the XCK signal to control the further transmission of the signal inside the circuit, as well as the control of the subsequent fifth switching transistor M5. The second terminal of the fifth switching transistor M5 is connected to the second terminal of the sixth switching transistor M6, which means that the fifth switching transistor M5 and the sixth switching transistor M6 form a signal output path. The second clock signal XCK controls the fifth switching transistor M5 to turn on, and cooperates with the sixth switching transistor M6 to convert the voltage difference between the first power supply voltage VGH and the second power supply voltage VGL into the first node voltage. The generation of the first node voltage depends on the operating state of the fifth switching transistor M5 and the sixth switching transistor M6, as well as the time sequence control of the first clock signal CK and the second clock signal XCK.

Through the complex switching transistor connection and time sequence control, the first output control module can accurately generate the first node voltage for the control of subsequent circuits, such as adjusting the high level duration of the light-emitting control signal or affecting the data writing process in the pixel circuit. This design is an important part of signal control and conversion in the driving circuit, and plays a key role in optimizing the display effect of the display panel, especially in reducing flicker phenomenon at low refresh frequencies, such as 60 Hz or 45 Hz.

In a display device with a low refresh frequency, by precisely controlling the state of the switching transistor in the first output control module and the transmission of the signal, the time sequence and intensity of the signal can be optimized to ensure the stable generation of the light-emitting control signal, so as to improve the display quality and reduce the flicker perception caused by periodical changes of the signal.

Referring to FIG. 7, the first output control module 20 further includes a first capacitor C1. A first plate of the first capacitor C1 is connected to the second terminal of the fourth switching transistor M4, and a second plate of the first capacitor C1 is connected to the first terminal of the third switching transistor M3.

It can be understood that the design of adding the first capacitor in the first output control module is to further stably and accurately control the first node voltage. The capacitor plays an important role in storing charges, smoothing voltage fluctuations and filtering in circuit design.

The first plate of the first capacitor is connected to the second terminal of the fourth switching transistor M4, and the second plate is connected to the first terminal of the third switching transistor M3. This connection mode means that the capacitor is located on the signal path between the fourth switching transistor M4 and the third switching transistor M3, and performs charge storage and voltage adjustment on the influence of the power supply voltage and the signal transmission between the switching transistors. When the second switching transistor M2 is turned on and the fourth switching transistor M4 is affected by the second power supply voltage VGL, the first capacitor starts to charge and store charge. When the third switching transistor M3 and the fifth switching transistor M5 are turned on under the control of the second clock signal XCK, the first capacitor releases the stored charge, smoothes the voltage fluctuations, and ensures the stable generation of the first node voltage. When the switching transistor switches state, the first capacitor helps to reduce voltage transients and improve signal quality.

During the signal processing process, especially when the switching transistor changes from on to off or from off to on, the voltage and signal may change instantaneously, which can affect the final display effect. The first capacitor can smooth these transients through its charging and discharging characteristics, reduce noise in the signal, and improve the purity of the first node voltage, so as to optimize the generation of the light-emitting control signal. The first capacitor can also introduce a certain signal delay, which is necessary in circuit design to ensure that the signal propagates between the various switching transistors in the correct time sequence. This delay helps to stabilize the signal and avoids unstable states caused by rapid signal changes, such as voltage spikes or signal distortion, which is particularly important for maintaining the normal operation of the display panel and avoiding flicker phenomenon.

In summary, the first capacitor C1 in the first output control module adjusts and smoothes the voltage between the fourth switching transistor M4 and the third switching transistor M3 through its specific position in the circuit and its charge and discharge characteristics to ensure the stable generation of the first node voltage. This design not only improves the signal quality, but also increases the stability and accuracy of signal transmission, which is of great significance for optimizing the display effect, especially reducing flicker phenomenon in display panels with low refresh frequencies, such as 60 Hz or 45 Hz. Through the filtering and smoothing effect of the first capacitor C1, the signal can be kept pure and stable even in the processes of complex signal processing and state conversion of the switching transistor, so as to ensure the optimization of display quality.

As shown in FIG. 7, the second output control module 30 includes a first processing submodule 301 and a second processing submodule 302. The first processing submodule receives the first power supply voltage and outputs a first processing signal and a second processing signal in response to the first clock signal and the second clock signal. The first processing signal is applied to the first output control module, and the second processing signal is applied to the second processing submodule. The second processing submodule receives the second power supply voltage, and generates the second node voltage in response to the first clock signal, the second clock signal, the second processing signal and the output of the input module.

In some embodiments of the present disclosure, the first processing submodule receives the first power supply voltage VGH, that is, the first processing submodule can operate according to the level state of the first power supply voltage VGH. The first clock signal CK and the second clock signal XCK control the signal to accurately adjust the operating rhythm of the first processing submodule, so as to ensure that the generation and transmission of the signal are coordinated with the time sequence of the entire display driving circuit. Under the control of the first clock signal CK and the second clock signal XCK, the first processing submodule generates two processing signals. The first processing signal is applied to the first output control module, which can be used to assist in generating the first node voltage or adjust the operating state of the first output control module. The second processing signal is sent to the second processing submodule for the generation process of the second node voltage.

The second processing submodule receives a second power supply voltage VGL, which provides a ground level or a negative voltage for the off state of the transistor, or as a reference voltage in the circuit. The second processing submodule not only relies on the time sequence control (the first clock signal and the second clock signal), but also requires the second processing signal and the signal transmitted from the input module as input to generate the second node voltage. The second node voltage is the main output of the second processing submodule, which is used in the subsequent circuit to control the specific state of the pixel.

The second output control module generates the second node voltage through the cooperation of the first processing submodule and the second processing submodule. First, the first processing submodule outputs two processing signals according to the level of VGH under the time sequence control of the first clock signal CK and the second clock signal XCK: the first processing signal is used for feedback control or adjustment of the state of the first output control module; and the second processing signal provides the necessary input for the second processing submodule. Subsequently, after receiving the second power supply voltage VGL, the first clock signal CK, the second clock signal XCK, the second processing signal and the signal from the input module, the second processing submodule generates the second node voltage by integrating the above information. The generation of the second node voltage not only takes into account the influence of the second power supply voltage VGL, but also accurately responds to the rhythm of the clock signal and the state of the signal from the first processing submodule to ensure the stability and accuracy of the second node voltage.

In display devices with low refresh frequencies, such as panels with a fundamental frequency of 60 Hz or 45 Hz, the precise operation of the second output control module is essential for generating a stable and accurate light-emitting control signal. Through the interaction between the first processing submodule and the second processing submodule, the circuit can optimize the signal processing process, reduce signal delay and distortion, so as to reduce the flicker phenomenon caused by cyclical changes in the signal and improve the display quality. This design ensures that when controlling the light-emitting state of the pixel, the high and low level durations of the light-emitting control signal can be accurately adjusted, so as to stabilize the brightness of the display panel and reduce the flicker or brightness changes that may be perceived by the user.

As shown in FIG. 7, the first processing submodule 301 includes a seventh switching transistor M7, an eighth switching transistor M8 and a ninth switching transistor M9. A second terminal of the seventh switching transistor M7 and a control terminal of the eighth switching transistor M8 are both connected to an output terminal of the input module 10, a control terminal of the seventh switching transistor M7 receives the second clock signal, a first terminal of the seventh switching transistor M7 is connected to a first terminal of the ninth switching transistor M9, a second terminal of the ninth switching transistor M9 receives the first power supply voltage VGH, a control terminal of the ninth switching transistor M9 is connected to a first terminal of the eighth switching transistor M8, the second terminal of the eighth switching transistor M8 receives the first clock signal, the first terminal of the eighth switching transistor M8 outputs the first processing signal, and the second terminal of the seventh switching transistor M7 outputs the second processing signal.

The second terminal of the seventh switching transistor M7 is connected to the output terminal of the input module to receive the signal transmitted from the circuit of the previous stage. The control terminal of the seventh switching transistor M7 receives the second clock signal XCK to control the on and off of the seventh switching transistor M7. The first terminal of the seventh switching transistor M7 is connected to the first terminal of the ninth switching transistor M9. When the seventh switching transistor M7 is turned on, the signal can be transmitted to the ninth switching transistor M9 to affect the generation of the first node voltage. The second terminal of the seventh switching transistor M7 is also used to output the second processing signal, which means that the second terminal of the seventh switching transistor M7 is not only participates in the internal processing of the signal, but also feeds back part of the signal to other parts of the second output control module.

The control terminal of the eighth switching transistor M8 is connected to the output terminal of the input module to receive the signal transmitted from the circuit of the previous stage. The first terminal of the eighth switching transistor M8 is connected to the control terminal of the ninth switching transistor M9, and is also the output terminal of the first processing signal. When the eighth switching transistor M8 is turned on, the state of the ninth switching transistor M9 can be affected, and the generation of the first node voltage is further affected. The second terminal of the eighth switching transistor M8 receives the first clock signal CK. The first clock signal CK not only controls the on and off of the eighth switching transistor M8, but also affects the internal state of the eighth switching transistor M8 as a reference voltage when it is turned off.

The first terminal of the ninth switching transistor M9 is connected to the first terminal of the seventh switching transistor M7 to receive the signal. The second terminal of the ninth switching transistor M9 receives the first power supply voltage VGH, which is the power supply when the ninth switching transistor M9 is turned on, and is used to generate or adjust the voltage. The control terminal of the ninth switching transistor M9 is connected to the first terminal of the eighth switching transistor M8 to receive the first processing signal. The level state of the first processing signal determines whether the ninth switching transistor M9 is turned on and how it affects the generation of the first node voltage.

When the second clock signal XCK controls the seventh switching transistor M7 to turn on, the seventh switching transistor M7 receives the signal from the input module, transmits the signal to the first terminal of the ninth switching transistor M9, and outputs the second processing signal. At the same time, the first clock signal CK controls the eighth switching transistor M8 to turn on, and the signal at the first terminal thereof can affect the state of the ninth switching transistor M9, causing the ninth switching transistor M9 to turn on or off, so as to adjust the generation of the first node voltage. Under the control of the first clock signal CK and the second clock signal XCK, the first processing signal and the second processing signal are output from the first terminal of the eighth switching transistor M8 and the second terminal of the seventh switching transistor M7, respectively. The first processing signal is mainly used to affect the ninth switching transistor M9, so as to adjust the first node voltage. The second processing signal is used for feedback control, or affects other parts of the second output control module, such as the second processing submodule, to generate the second node voltage.

This design utilizes the precise control of the first clock signal CK and the second clock signal XCK, and combines the use of the first power supply voltage VGH and the second power supply voltage VGL. Through the switching action of the transistor, the first processing signal and the second processing signal are generated and transmitted to precisely control the first node voltage, ensuring that the display panel can emit light stably and reduce flicker phenomenon at different refresh frequencies, such as 60 Hz or 45 Hz. At the same time, the generation and transmission of the second processing signal provides coordination and feedback for other parts of the display driving circuit, which contributes to the stable operation of the entire display driving circuit and the precise control of the signal. This fine signal control mechanism is the key to optimizing the display effect and improving the display quality, especially in low refresh frequency applications, which can effectively reduce the visual discomfort caused by periodical changes in the signal.

Referring to FIG. 7, the second processing submodule 302 includes a tenth switching transistor M10, an eleventh switching transistor M11 and a twelfth switching transistor M12. A control terminal of the tenth switching transistor M10 and a first terminal of the eleventh switching transistor M11 are connected to the output terminal of the input module 10, a second terminal of the eleventh switching transistor M11 is connected to the output module, a control terminal of the eleventh switching transistor M11 receives the second power supply voltage, a first terminal of the tenth switching transistor M10 is connected to a first terminal of the twelfth switching transistor M12, a second terminal of the tenth switching transistor M10 receives the second clock signal, a control terminal of the twelfth switching transistor M12 receives the first clock signal, and the second terminal of the eleventh switching transistor M11 outputs the second node voltage through the second node n2.

In the above connection relationship, the control terminal of the tenth switching transistor M10 is connected to the output terminal of the input module 10 to receive the signal or data transmitted from the input module 10, and the signal is used for subsequent signal processing. The first terminal of the tenth switching transistor M10 is connected to the first terminal of the twelfth switching transistor M12. When the tenth switching transistor M10 is turned on, it can transmit the signal to the twelfth switching transistor M12 and participate in the generation of the second node voltage. The second terminal of the tenth switching transistor M10 receives the second clock signal XCK, and the second clock signal XCK is used to control the on and off of the tenth switching transistor M10, to ensure that the signal is transmitted to the twelfth switching transistor M12 at the correct time point, thereby affecting the generation of the second node voltage.

The first terminal of the eleventh switching transistor M11 is connected to the output terminal of the input module 10 to receive the signal or data. The second terminal of the eleventh switching transistor M11 directly outputs the second node voltage, is connected to the output module 40, and transmits the generated second node voltage to the subsequent circuit or the pixel circuit of the display panel. The control terminal of the eleventh switching transistor M11 receives the second power supply voltage VGL, and the second power supply voltage VGL is used as a reference voltage or a ground level. When the eleventh switching transistor M11 is turned on, the second power supply voltage VGL can affect the output second node voltage through the eleventh switching transistor M11, thereby facilitating providing a stable reference point in the generation of the second node voltage.

The first terminal of the twelfth switching transistor M12 is connected to the first terminal of the tenth switching transistor M10 to receive the signal. The control terminal of the twelfth switching transistor M12 receives the first clock signal CK, and the first clock signal CK is used to control the on or off of the twelfth switching transistor M12, which affects the generation of the second node voltage. The second terminal of the twelfth switching transistor M12 is connected to the second terminal of the eleventh switching transistor M11. When turned on, the twelfth switching transistor M12 can operate in conjunction with the eleventh switching transistor M11 to generate and output the second node voltage.

In the second processing submodule, the signal processing and the generation of the second node voltage mainly depend on the time sequence control of the first clock signal CK and the second clock signal XCK, as well as the reference voltage function of the second power supply voltage VGL. In some embodiments of the present disclosure, the second clock signal XCK controls the tenth switching transistor M10 to turn on, and the signal is transmitted from the input module to the twelfth switching transistor M12 and the eleventh switching transistor M11 via the tenth switching transistor M10. At the same time, the first clock signal CK controls the twelfth switching transistor M12 to turn on, and operates in conjunction with the signal of the tenth switching transistor M10 and the state of the eleventh switching transistor M11 to generate the second node voltage. The eleventh switching transistor M11 maintains a stable reference point under the action of the second power supply voltage VGL, and adjusts the level of the second node voltage according to the signal transmitted from the tenth switching transistor M10 and the twelfth switching transistor M12.

This design ensures the accurate generation and control of the second node voltage, which not only depends on the signal received from the input module, but also is affected by the time sequence control of the first clock signal and the second clock signal, as well as the stabilizing effect of the second power supply voltage. The generation and control of the second node voltage is crucial for the driving of the display panel, and it can directly affect the operating state of the pixel circuit. In display applications with low refresh frequencies, such as 60 Hz or 45 Hz, accurate generation of the second node voltage facilitates reducing flicker phenomenon and improving display quality.

In summary, the second processing submodule generates and outputs the second node voltage through the coordinated operation of the tenth switching transistor M10, the eleventh switching transistor M11 and the twelfth switching transistor M12, under the precise time sequence control of the first clock signal CK and the second clock signal XCK, combined with the stable reference of the second power supply voltage VGL. This is a key step in controlling the pixel state of the display panel and optimizing the display effect.

It should be noted that the switching transistors included in each of the above stages are all PMOS transistors. PMOS transistor is a P-channel metal oxide semiconductor field-effect transistor. PMOS transistor is a semiconductor device whose operation principle is different from that of N-channel MOS transistor, i.e., NMOS transistor. In the PMOS transistor, when the gate voltage is lower than the source and drain voltages, the PMOS transistor is turned on, allowing current to flow from the source to the drain. On the contrary, when the gate voltage is higher, the PMOS transistor is turned off, preventing current from passing. This characteristic of PMOS transistor makes it commonly used in digital circuits to construct logic circuits, such as inverters and logic gates, and as a current control element in power supply circuits. The display driving circuit is configured to control the pixels on the display panel so that it displays according to the predetermined image information. In the circuit, the function of the switching transistor is to connect or disconnect the path between the power supply and the load (such as OLED pixels) according to the logic state of the control signal, so as to control the light emission of the pixel. Using PMOS transistor as a switching transistor means that when the control signal level is low, the PMOS transistor is turned on, allowing current to pass, which is usually used to control the opening of OLED pixels in the driving circuit, i.e., the light-emitting state. On the contrary, when the control signal level is high, the PMOS transistor is turned off and the pixel is in a non-light-emitting state. In the display driving circuit, multi-stage cascade switching transistors are usually designed to control the step-by-step transmission and processing of the signal. If all the switching transistors at all stages are PMOS transistors, it would facilitate the layout of the circuit and the coordination of the signal, ensuring that the signal is stably and accurately transmitted in the multi-stage circuit, so as to achieve high-quality display effects.

In summary, the use of PMOS transistor as switching transistor in the driving circuit of the display panel is based on the consideration of voltage control, power efficiency and signal integrity in circuit design. Through the low-level conduction characteristics of PMOS transistor, precise control of the display signal can be achieved, ensuring that the display panel can provide high-quality and stable display effects under various operating conditions.

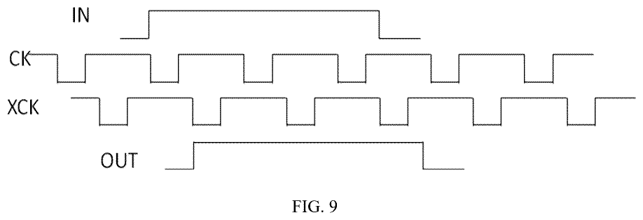

The time sequence design diagram of the light-emitting control signal is shown in FIG. 9. The IN signal usually represents input data or the control signal, which can be a data signal from the circuit of the previous stage, or a control signal used to start the operation of the entire circuit. The change of the IN signal triggers a specific operation of the circuit, such as data writing and state switching. The CK signal, i.e., the first clock signal, is the key to synchronous operation in the circuit, which is usually a cyclical square wave signal used to synchronize the operation of various parts of the circuit to ensure that the signal is processed and transmitted at the correct time point. The high level and low level of the first clock signal represent the activation and waiting states of signal processing, respectively, which helps the circuit to achieve accurate reading and writing of data. The XCK signal, i.e., the second clock signal, is an extended clock signal with a different cycle or phase from the first clock signal. The introduction of the second clock signal is to meet the special time sequence requirements of certain parts of the circuit, such as requiring a longer or shorter time to complete data processing or state switching. In an embodiment of the present disclosure, the cooperation of the second clock signal with the first clock signal can realize more complex circuit operations and signal control. The OUT signal is the output signal of the circuit, which is a processed data signal, or a control signal finally generated by the circuit, such as a light-emitting control signal. The change of the OUT signal reflects the result of the internal processing of the circuit and is the final output implemented by the circuit function. In an embodiment of the present disclosure, the generation and change of the OUT signal depend on the time sequence control of the IN signal, the CK signal and the XCK signal.

In circuit design, especially in display driving circuits, accurate time sequence control is very important because it directly affects the synchronization of signals and the stability of display effects. By analyzing the time sequence diagrams of the IN signal, the CK signal, the XCK signals, and the OUT signal, it can be understood that how the circuit processes the input signal, how it is controlled by the clock signal, and how it generates the output signal. This is crucial for understanding the operating principle, optimizing the design, and troubleshooting of the circuit.

Referring to FIG. 7 again, the output module 40 includes a thirteenth switching transistor M13 and a fourteenth switching transistor M14. A control terminal of the thirteenth switching transistor M13 receives the first node voltage, the first terminal of the thirteenth switching transistor M13 receives the first power supply voltage VGH, a second terminal of the thirteenth switching transistor M13 is connected to a first terminal of the fourteenth switching transistor M14, a control terminal of the fourteenth switching transistor M14 receives the second node voltage, a second terminal of the fourteenth switching transistor M14 receives the second power supply voltage VGL, and the common node of the second terminal of the thirteenth switching transistor M13 and the first terminal of the fourteenth switching transistor M14 outputs the light-emitting control signal.

In some embodiments of the present disclosure, the control terminal of the thirteenth switching transistor M13 receives the first node voltage, which is a key signal for controlling the on or off state of the thirteenth switching transistor M13. When the first node voltage reaches a certain level value, the thirteenth switching transistor M13 is turned on, allowing current or voltage to pass. The first terminal of the thirteenth switching transistor M13 receives the first power supply voltage VGH, which is the positive power supply of the circuit, usually a high voltage level. When the thirteenth switching transistor M13 is turned on by the first node voltage signal, the first power supply voltage VGH passes through the thirteenth switching transistor M13, affecting the voltage state of the subsequent circuit. The second terminal of the thirteenth switching transistor M13 is connected to the first terminal of the fourteenth switching transistor M14, and the node formed by the second terminal of the thirteenth switching transistor M13 and the first terminal of the fourteenth switching transistor M14 is the output point of the light-emitting control signal.

The control terminal of the fourteenth switching transistor M14 receives the second node voltage, which is another key signal for controlling the on or off state of the fourteenth switching transistor M14. The level value of the second node voltage determines whether the fourteenth switching transistor M14 is turned on. The first terminal of the fourteenth switching transistor M14 is connected to the second terminal of the thirteenth switching transistor M13 to receive the signal or voltage passing through the thirteenth switching transistor M13. This terminal is also the output point of the light-emitting control signal. The second terminal of the fourteenth switching transistor M14 receives the second power supply voltage VGL, which is the negative power supply or ground level of the circuit. When the fourteenth switching transistor M14 is turned on by the second node voltage signal, the second power supply voltage VGL affects the generation of the light-emitting control signal.

The node connecting the second terminal of the thirteenth switching transistor M13 and the first terminal of the fourteenth switching transistor M14 is the output point of the light-emitting control signal. The generation of the light-emitting control signal depends on the states of the thirteenth switching transistor M13 and the fourteenth switching transistor M14, that is, depends on whether they are turned on by the corresponding first node voltage signal and second node voltage signal. When the thirteenth switching transistor M13 and the fourteenth switching transistor M14 are turned on at the same time, the light-emitting control signal is the difference between the first power supply voltage VGH and the second power supply voltage VGL or a certain state, and this state is used to control the light emission or non-light emission of the pixels in the display panel, so as to affect the display effect.

The generation of the light-emitting control signal needs to be combined with the control of the first node voltage and the second node voltage. In some embodiments of the present disclosure, when the first node voltage reaches a sufficient level to turn on the thirteenth switching transistor M13, the first power supply voltage VGH reaches the common node through the thirteenth switching transistor M13. Subsequently, the level state of the second node voltage determines whether the fourteenth switching transistor M14 is turned on. If the fourteenth switching transistor M14 is also turned on, the second power supply voltage VGL reaches the common node through the fourteenth switching transistor M14. When both the thirteenth switching transistor M13 and the fourteenth switching transistor M14 are turned on, the common node generates a light-emitting control signal to indicate the pixel circuit to start emitting light.

This design ensures accurate generation and control of the light-emitting control signal, enabling the display panel to stably display images at different refresh frequencies and reduce flicker phenomenon caused by the mismatch of the time sequence of the signal or unstable voltage. The coordinated effect of the thirteenth switching transistor and the fourteenth switching transistor is the key to generating accurate light-emitting control signals in the driving circuit, which directly affects the quality of the display effect and the user's visual experience. In applications with low refresh frequencies, such as display panels with refresh frequencies of 60 Hz or 45 Hz, this precise control is particularly important because it can effectively reduce flicker and improve display comfort and clarity.

Referring to FIG. 7 again, the output module 40 further includes a second capacitor C2 and a third capacitor C3. A first plate of the second capacitor C2 is connected to the control terminal of the fourteenth switching transistor M14, and a second plate of the second capacitor C2 is connected to the second output control module 30. A first plate of the third capacitor C3 is connected to the control terminal of the thirteenth switching transistor M13, and a second plate of the third capacitor C3 receives the first power supply voltage VGH.

It can be understood that the first plate of the second capacitor is connected to the control terminal of the fourteenth switching transistor M14, i.e., the terminal receiving the second node voltage. The second plate of the second capacitor is connected to the second output control module, and can be directly or indirectly connected to the second node voltage signal source, or other parts of the circuit related to the second node voltage signal. The first plate of the third capacitor is connected to the control terminal of the thirteenth switching transistor M13, which means that the third capacitor directly participates in the adjustment of the control signal (first node voltage) of the thirteenth switching transistor M13. The second plate of the third capacitor receives the first power supply voltage VGH, which indicates that one terminal of the third capacitor is fixed to the positive power supply potential of the circuit.

The main function of the second capacitor is to smooth and stabilize the second node voltage. When the second node voltage signal changes rapidly, the second capacitor can mitigate these changes, ensuring that the voltage fluctuation at the control terminal of the fourteenth switching transistor M14 is not too severe, so as to improve the stability and reliability of the light-emitting control signal. One of the main functions of the third capacitor is to smooth the voltage fluctuation at the control terminal of the thirteenth switching transistor M13 (the terminal receiving the first node voltage signal). Since the first node voltage signal changes rapidly in a short time, this change causes the control state of the thirteenth switching transistor M13 to be unstable, so as to affect the generation of the light-emitting control signal. By introducing the third capacitor between the control terminal of the thirteenth switching transistor M13 and the first power supply voltage VGH, it is possible to absorb or release charges when the signal changes, mitigate the rapid fluctuation of the first node voltage signal, and ensure a smooth transition of the control state of the thirteenth switching transistor M13. When the first node voltage signal needs to be maintained at a certain level for a period of time to control the state of the thirteenth switching transistor M13, the third capacitor can help maintain this level. Even if the voltage of the first node voltage signal source fluctuates, the third capacitor can help stabilize the voltage of the control terminal of the thirteenth switching transistor M13 by storing and releasing charges, ensuring that the state of the switching transistor does not change due to instantaneous voltage fluctuation.

In display applications with low refresh frequencies, such as 60 Hz or 45 Hz, the cycle and stability of the light-emitting control signal are crucial for reducing flicker phenomenon. The addition of the second capacitor can ensure that the level of the light-emitting control signal changes more smoothly when the signal cycle changes, avoiding the instability of the light-emitting control signal caused by the rapid change of the second node voltage signal, so as to improve the display effect and reduce flicker. The second plate of the second capacitor is connected to the second output control module, which means that it not only affects the control of the fourteenth switching transistor M14, but also interacts with other circuit elements to participate in a wider range of signal processing and control. This connection mode indicates that the second capacitor not only plays a role in the local circuit, but also participates in the overall coordination and feedback control of the circuit.

The third capacitor indirectly affects the generation of the light-emitting control signal by stabilizing the control terminal voltage of the thirteenth switching transistor. In display applications with low refresh frequencies, such as 60 Hz or 45 Hz, accurate control of the light-emitting control signal is crucial for reducing flicker phenomenon and improving display quality. The presence of the third capacitor can ensure that the state change of the thirteenth switching transistor M13 is more controllable when receiving the first power supply voltage VGH and interacting with the first node voltage signal, so as to generate a more stable and accurate light-emitting control signal.

In summary, the main purpose of adding the second capacitor to the output module is to stabilize and optimize the second node voltage, so as to ensure that the generation and control of the light-emitting control signal are more accurate and reduce the flicker phenomenon that may occur in the display applications with low refresh frequencies. The second capacitor plays a key role in signal adjustment of the circuit by connecting to the fourteenth switching transistor and the second output control module, and is an important component in improving the stability and quality of display effects in the display driving circuit design. The core purpose of adding the third capacitor to the output module is to smooth and stabilize the control signal (first node voltage) of the thirteenth switching transistor, ensuring that the thirteenth switching transistor is not affected by voltage fluctuations when controlling the generation of the light-emitting control signal, so as to optimize the operation performance of the display panel, especially reducing flicker phenomenon in the applications with low refresh frequencies and improving display quality. This design detail reflects a deep understanding of the requirements for control accuracy of the signal and circuit stability in the display driving circuit.

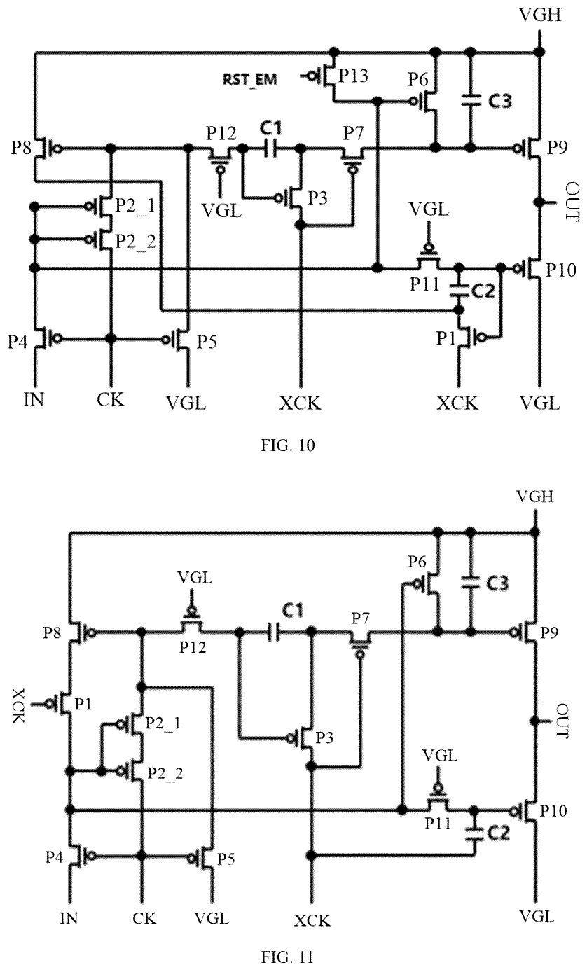

In some embodiments of the present disclosure, the driving circuit in FIG. 10 and FIG. 11 can also be used to generate the light-emitting control signal.

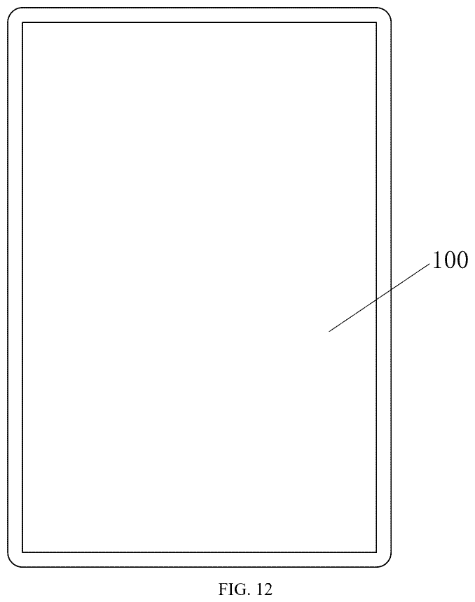

On the basis of the above, the present disclosure provides a display apparatus, as shown in FIG. 12. FIG. 12 is a schematic diagram of a display apparatus according to some embodiments of the present disclosure. The display apparatus includes the display panels 100 according to any one of the above embodiments. The display apparatus can be at least one of a wearable device, a camera, a mobile phone, a tablet computer, a display screen, a television, and a vehicle-mounted display terminal. The display apparatus includes the display panel according to the above embodiments, and has all the beneficial effects of the above display panel.

The above descriptions are only some specific embodiments disclosed in the present disclosure and are not intended to limit the present disclosure. For those skilled in the art, the present disclosure may have various modifications and variations. Any modification, equivalent replacement, improvement, and the like made within the spirit and principle of the present disclosure shall fall within the protection scope of the present disclosure.

What is claimed is:

1. A display panel, comprising a pixel circuit, wherein the pixel circuit comprises a driving transistor, a light-emitting control transistor and a light-emitting device;
wherein a first electrode of the driving transistor is electrically connected to a power supply voltage terminal, and a second electrode of the driving transistor is electrically connected to a first electrode of the light-emitting control transistor;
wherein a second electrode of the light-emitting control transistor is electrically connected to an electrode of the light-emitting device, and a gate of the light-emitting control transistor is connected to a light-emitting control signal line to receive a light-emitting control signal transmitted by the light-emitting control signal line;
wherein in one cycle of the light-emitting control signal, the light-emitting control signal comprises a plurality of pulses, one of the plurality of pulses comprises one non-enable level and one enable level that are adjacent to each other, the plurality of pulses of the light-emitting control signal comprise a first pulse and a second pulse, a non-enable level duration of the first pulse is S1, and a non-enable level duration of the second pulse is S2, wherein S1>S2; and
wherein a reference refresh frequency of the display panel is F0, in a first display mode, one picture refresh frame of the display panel comprises a data writing frame, and a frequency of the light-emitting control signal in the data writing frame is F1, wherein F1>F0.

2. The display panel according to claim 1, wherein in one cycle of the light-emitting control signal, a number of the first pulse of the light-emitting control signal is N1, a number of the second pulse is N2, N2=k1×N1, where k1 is a positive integer, and k1≥2.

3. The display panel according to claim 2, wherein N1 is negatively correlated with F0, and N2 is positively correlated with F0.

4. The display panel according to claim 2, wherein one cycle of the light-emitting control signal comprises a plurality of groups of pulses, and any one of the groups of pulses comprises one first pulse and a plurality of second pulses subsequent to the first pulse.

5. The display panel according to claim 4, wherein in the first display mode, one picture refresh frame of the display panel further comprises M light-emitting holding frames, wherein M≥1; and in the light-emitting holding frames, the frequency of the light-emitting control signal is F1.

6. The display panel according to claim 1, wherein F1=k2×F0, where k2 is a positive integer, and k2≥2.

7. The display panel according to claim 1, wherein S1=k3×S2, where k3 is a positive integer, and k3≥2.

8. The display panel according to claim 1, wherein the pixel circuit further comprises a data writing transistor and a bias adjustment transistor; a first electrode of the data writing transistor is electrically connected to a data line, and a second electrode of the data writing transistor is electrically connected to the first electrode of the driving transistor; a first electrode of the bias adjustment transistor is electrically connected to the first electrode of the driving transistor, a second electrode of the bias adjustment transistor is electrically connected to a bias adjustment signal line, and a gate of the bias adjustment transistor is electrically connected to a first scanning signal line to receive a first scanning signal; in the data writing frame, a number of cycles of the light-emitting control signal is N, wherein N≥2; one pulse of the first scanning signal comprises an enable level and a non-enable level; the enable level of the first scanning signal overlaps with the non-enable level of the first pulse of the light-emitting control signal.

9. The display panel according to claim 1, wherein the reference refresh frequency F0 of the display panel satisfies F0≤90 Hz.

10. The display panel according to claim 9, wherein the reference refresh frequency F0 of the display panel is 60 Hz or 45 Hz.

11. The display panel according to claim 1, further comprising a driving circuit, wherein the driving circuit comprises a light-emitting driver configured to generate the light-emitting control signal, the light-emitting driver comprises a plurality of stages, each of the plurality of stages is configured to receive an input signal, a first clock signal, a second clock signal, a first power supply voltage and a second power supply voltage, and output the light-emitting control signal, and
wherein each of the plurality of stages comprises:
an input module configured to receive and respond to the input signal and the first clock signal to output a stage transmission to a previous stage;
a first output control module configured to receive the first power supply voltage and the second power supply voltage, and generate a first node voltage in response to the first clock signal and the second clock signal;
a second output control module configured to receive the first power supply voltage and the second power supply voltage, and generate a second node voltage in response to the first clock signal and the second clock signal; and
an output module configured to receive the first power supply voltage and the second power supply voltage, and generate the light-emitting control signal in response to the first node voltage and the second node voltage.

12. The display panel according to claim 11, wherein the input module comprises a first switching transistor, a control terminal of the first switching transistor is configured to receive the first clock signal, a first terminal of the first switching transistor is configured to receive the input signal, and a second terminal of the first switching transistor is an output terminal.

13. The display panel according to claim 11, wherein the first output control module comprises a second switching transistor, a third switching transistor, a fourth switching transistor, a fifth switching transistor and a sixth switching transistor,
wherein a control terminal of the second switching transistor is configured to receives the first clock signal, a second terminal of the second switching transistor and a control terminal of the fourth switching transistor are configured to receive the second power supply voltage, a first terminal of the second switching transistor is connected to a control terminal of the third switching transistor and a first terminal of the fourth switching transistor, respectively, a first terminal of the third switching transistor is connected to a second terminal of the fourth switching transistor and a first terminal of the fifth switching transistor, respectively, a second terminal of the third switching transistor and a control terminal of the fifth switching transistor are configured to receive the second clock signal, a second terminal of the fifth switching transistor is connected to a second terminal of the sixth switching transistor, a first terminal of the sixth switching transistor is configured to receive the first power supply voltage, and a control terminal of the sixth switching transistor is connected to an output terminal of the input module, and wherein the second terminal of the sixth switching transistor is configured to output the first node voltage.

14. The display panel according to claim 13, wherein the first output control module further comprises a first capacitor, a first plate of the first capacitor is connected to the second terminal of the fourth switching transistor, and a second plate of the first capacitor is connected to the first terminal of the third switching transistor.

15. The display panel according to claim 11, wherein the second output control module comprises:
a first processing submodule configured to receive the first power supply voltage and output a first processing signal and a second processing signal in response to the first clock signal and the second clock signal, wherein the first processing signal is applied to the first output control module; and
a second processing submodule configured to receive the second power supply voltage and generate the second node voltage in response to the first clock signal, the second clock signal, the second processing signal and an output of the input module, wherein the second processing signal is applied to the second processing submodule.

16. The display panel according to claim 15, wherein the first processing submodule comprises a seventh switching transistor, an eighth switching transistor and a ninth switching transistor,
wherein a second terminal of the seventh switching transistor and a control terminal of the eighth switching transistor are connected to an output terminal of the input module, a control terminal of the seventh switching transistor is configured to receive the second clock signal, a first terminal of the seventh switching transistor is connected to a first terminal of the ninth switching transistor, a second terminal of the ninth switching transistor is configured to receive the first power supply voltage, a control terminal of the ninth switching transistor is connected to a first terminal of the eighth switching transistor, a second terminal of the eighth switching transistor is configured to receive the first clock signal, the first terminal of the eighth switching transistor is configured to output the first processing signal, and the second terminal of the seventh switching transistor is configured to output the second processing signal.

17. The display panel according to claim 15, wherein the second processing submodule comprises a tenth switching transistor, an eleventh switching transistor and a twelfth switching transistor,
wherein a control terminal of the tenth switching transistor and a first terminal of the eleventh switching transistor are connected to an output terminal of the input module, a second terminal of the eleventh switching transistor is connected to the output module, a control terminal of the eleventh switching transistor is configured to receive the second power supply voltage, a first terminal of the tenth switching transistor is connected to a first terminal of the twelfth switching transistor, a second terminal of the tenth switching transistor is configured to receive the second clock signal, and a control terminal of the twelfth switching transistor is configured to receive the first clock signal, and wherein the second terminal of the eleventh switching transistor is configured to output the second node voltage.

18. The display panel according to claim 11, wherein the output module comprises a thirteenth switching transistor and a fourteenth switching transistor, a control terminal of the thirteenth switching transistor is configured to receive the first node voltage, a first terminal of the thirteenth switching transistor is configured to receive the first power supply voltage, a second terminal of the thirteenth switching transistor is connected to a first terminal of the fourteenth switching transistor, a control terminal of the fourteenth switching transistor is configured to receive the second node voltage, a second terminal of the fourteenth switching transistor is configured to receive the second power supply voltage, and a common node of the second terminal of the thirteenth switching transistor and the first terminal of the fourteenth switching transistor are configured to output the light-emitting control signal.

19. The display panel according to claim 18, wherein the output module further comprises a second capacitor, a first plate of the second capacitor is connected to the control terminal of the fourteenth switching transistor, and a second plate of the second capacitor is connected to the second output control module.

20. The display panel according to claim 18, wherein the output module further comprises a third capacitor, a first plate of the third capacitor is connected to the control terminal of the thirteenth switching transistor, and a second plate of the third capacitor is configured to receive the first power supply voltage.

21. The display panel according to claim 11, wherein the first clock signal and the second clock signal have a same frequency, and there is a phase difference between the second clock signal and the first clock signal.

22. The display panel according to claim 12 wherein switching transistors of each of the stages are P-channel metal oxide semiconductor (PMOS) transistors.

23. A display apparatus, comprising a display panel, wherein the display panel comprises a pixel circuit, and the pixel circuit comprises a driving transistor, a light-emitting control transistor and a light-emitting device;
wherein a first electrode of the driving transistor is electrically connected to a power supply voltage terminal, and a second electrode of the driving transistor is electrically connected to a first electrode of the light-emitting control transistor;
wherein a second electrode of the light-emitting control transistor is electrically connected to an electrode of the light-emitting device, and a gate of the light-emitting control transistor is connected to a light-emitting control signal line to receive a light-emitting control signal transmitted by the light-emitting control signal line;
wherein in one cycle of the light-emitting control signal, the light-emitting control signal comprises a plurality of pulses, one of the plurality of pulses comprises one non-enable level and one enable level that are adjacent to each other, the plurality of pulses of the light-emitting control signal comprise a first pulse and a second pulse, a non-enable level duration of the first pulse is S1, and a non-enable level duration of the second pulse is S2, wherein S1>S2; and
wherein a reference refresh frequency of the display panel is F0, in a first display mode, one picture refresh frame of the display panel comprises a data writing frame, and a frequency of the light-emitting control signal in the data writing frame is F1, wherein F1>F0.
